(19) United States
(12) Patent Application Publication
(10) Pub. No.: US 2004/0100176 A1
(43) Pub. Date: May 27, 2004

(54) Organic electronic device that filters colors

(75) Inventor: Karl Pichler, Santa Clara, CA (US)

Correspondence Address: Siemens Corporation, Attn: Elsa Keller, Legal Administrator, Intellectual Property Department, 186 Wood Avenue South, Iselin, NJ, 08830, US

(73) Assignee: Osram Opto Semiconductors GmbH

(21) Appl. No.: 10/301,241

(22) Filed: Nov. 21, 2002

(51) Int. Cl. H01J 5/16

(52) U.S. Cl. 313/112

(57) ABSTRACT

An embodiment of the present invention pertains to an organic electronic device that uses a colored substrate to change an emission spectrum of light passing through the colored substrate. The colored substrate changes the emission spectrum of light passing through it by absorbing light at a portion of the wavelengths, or by absorbing light at a portion of the wavelengths and by reemitting a portion of the absorbed light at different wavelengths. The colored substrate is commercially available.

Another embodiment of the present invention pertains to an organic electronic device that uses a colored device cover on a top electrode to change the emission spectrum of light passing through the colored device cover. The colored device cover changes the emission spectrum of light passing through it by absorbing light at a portion of the wavelengths, or by absorbing light at a portion of the wavelengths and by reemitting a portion of the absorbed light at different wavelengths. The colored device cover is also commercially available.

### BACKGROUND OF THE INVENTION

1. Field of the Invention

This invention relates generally to an organic electronic device and in particular to an organic electronic device that filters colors.

2. Description of the Related Art

Organic electronic devices such as, for example, organic light emitting devices (“OLEDs”), solar cells, or light detectors are incorporated in OLED displays, solar cell arrays, or light detector arrays respectively. These organic electronic devices often have a limited choice of organic materials that emit, process, or detect specific colors while providing good performance characteristics such as efficiency, lifetime, and processing conditions. For example, in the particular case of OLEDs, the best overall choice of emissive materials still gives an emission spectrum (i.e., color) that is not perfect. It is not perfect because, for example, the emission spectrum is not narrow and this results in “impure” emission colors. Also, the development of some emitter materials is difficult and time-consuming even for only a slight change in emission spectrum from the emission spectrum produced from already established emitter materials. The emitter materials of OLEDs are comprised of, for example, polymers, molecules, oligomers, dentrimers as well as polymer blends, blends of polymers with small-molecule compounds, copolymers, doped materials, fluorescent or phosphorescent materials, and various combinations of these materials.

The OLED displays are used in, for example, mobile communication devices (e.g., cell phones and personal digital assistants) and information displays within cars or household appliances. It is important to provide a wide variety of colors to customers using products that incorporate these displays and it is also important to be able to quickly develop OLEDs with new emission colors. The development of new high-quality emitter materials (e.g., emitter materials having the desired processing conditions, cost, efficiency, stability, and lifetime), however, is costly and time-consuming.

Many approaches have been tried and also commercially developed in the past to achieve color-filtering or color-changing in displays. These approaches use color filters or luminescent color-changing materials (“CCM”) that are deposited or attached/laminated within the light-emitting device. FIG. 1 shows a prior art OLED 100 that incorporates a color filter or CCM. In FIG. 1, an anode 106 is deposited on a substrate 103. A conducting polymer layer 109 is deposited on the anode 106, and an emissive layer 112 is deposited on the conducting polymer layer 109. A cathode 115 is deposited on the emissive layer 112. Light is generated in the emissive layer 112 by the recombination of holes injected by the anode 106 and electrons from the cathode 115. In prior art approaches, if the OLED 100 is bottom emitting, then the color filter/CCM 118 (as shown by the dotted lines) can be placed at one or more of the following: the substrate 103 is deposited on a color filter/CCM 118 (in other words, the color filter/CCM 118 is deposited on the outer surface of the substrate 103); the color filter/CCM 118 is deposited on the substrate 103; the color filter/CCM 118 is deposited on the anode 106; or the conducting polymer layer 109 performs the function of the color filter/CCM 118. If the OLED 100 is top emitting, then the color filter/CCM 118 can be deposited on the cathode 115, or the color filter/CCM 118 is deposited on another transparent substrate that is placed on top of the OLED 100.

The approaches described above can be found in, for example, U.S. Pat. No. 5,126,214, PCT/GB96/00929, and PCT/GB98/01804. However, these references suffer from one or more of the following disadvantages: one or often many more processing, patterning, lamination, or packaging steps are used to achieve the change in emission spectrum, and increased cost and decreased reliability, display quality, or yield due to the increased number of steps. Approaches in which the color filter and/or the CCM is deposited on the interior of the display are especially troublesome because the color filter or CCM deposition and processing may compromise the performance of the emissive layer, a charge carrier injection/transport layer, and/or an electrode of the display. For example, in fabricating the display, the color filter or the CCM is deposited on the substrate. Then, a bottom electrode is deposited on the color filter or the CCM, emitter materials are deposited on the bottom electrode, a top electrode is deposited on the emitter materials, and a barrier layer is deposited on the top electrode to encapsulate the display. Because the bottom electrode was deposited on the color filter or the CCM, the bottom electrode may be compromised resulting in detrimental results such as an electrical short or an uneven bottom electrode.

For the foregoing reasons, there exists a need to change the emission spectrum of the light emitted or detected by the organic electronic device without changing the fabrication or processing of the organic electronic device.

### SUMMARY

Embodiments of the present invention are directed to, for example, changing the emission spectrum of the light emitted or detected by the organic electronic device without changing the fabrication or processing of the organic electronic device. A first embodiment of an organic electronic device is described. This embodiment of the device includes a colored substrate, a bottom electrode on the colored substrate, and an organic layer on the bottom electrode. The bottom electrode is substantially transparent and the colored substrate changes the emission spectrum of the light passing through the colored substrate.

A second embodiment of the organic electronic device is also described. This embodiment of the device includes a substrate, a bottom electrode on the substrate, an organic layer on the bottom electrode, a top electrode on the organic layer, and a colored device cover on the top electrode. The top electrode is substantially transparent and the colored device cover changes the emission spectrum of the light passing through the colored device cover.

A first embodiment of a method to fabricate the organic electronic device is described. This embodiment of the method includes depositing a colored substrate, depositing a bottom electrode on the colored substrate, and depositing an organic layer on the bottom electrode. The bottom electrode is substantially transparent and the colored substrate changes the emission spectrum of the light passing through the colored substrate.

A second embodiment of a method to fabricate the organic electronic device is described. This embodiment of the method includes depositing a substrate, depositing a bottom electrode on the substrate, depositing an organic layer on the bottom electrode, depositing a top electrode on the organic layer, and depositing a colored device cover on the top electrode. The top electrode is substantially transparent and the colored device cover changes the emission spectrum of the light passing through the colored device cover.

### BRIEF DESCRIPTION OF THE DRAWINGS

FIG. 1 shows a prior art OLED 100 that incorporates a color filter or a CCM.

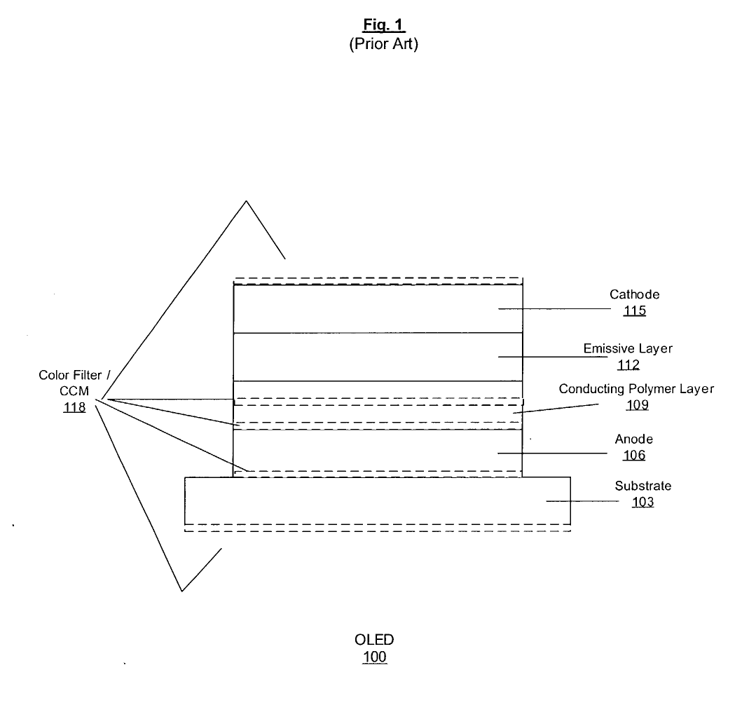

FIG. 2 shows a cross-sectional view of a first embodiment of an organic electronic device according to the present invention.

FIG. 3 shows a cross-sectional view of a second embodiment of an organic electronic device according to the present invention.

FIG. 4 shows a cross-sectional view of a third embodiment of an organic electronic device according to the present invention.

FIG. 5 shows an embodiment of a passive matrix OLED display according to the present invention.

### DETAILED DESCRIPTION

An embodiment of the present invention pertains to an organic electronic device that uses a colored substrate to change an emission spectrum of light passing through the colored substrate. The colored substrate changes the emission spectrum of light passing through it by absorbing light at a portion of the wavelengths, or by absorbing light at a portion of the wavelengths and by reemitting a portion of the absorbed light at different wavelengths.

Another embodiment of the present invention pertains to an organic electronic device that uses a colored device cover on a top electrode to change the emission spectrum of light passing through the colored device cover. The colored device cover changes the emission spectrum of light passing through it by absorbing light at a portion of the wavelengths, or by absorbing light at a portion of the wavelengths and by reemitting a portion of the absorbed light at different wavelengths.

Yet another embodiment of the present invention pertains to an organic electronic device in which light enters or exits the device from both sides. For example, if the organic electronic device is an OLED then light is emitted from both sides, or if the organic electronic device is a solar cell or a light detector, then it receives light from both sides. In this embodiment, the colored substrate and the colored device cover are both used to change the emission spectrum of light passing through them. Here, the colored substrate and the colored device cover may have the same or may have different color filtering properties, e.g., the substrate and the cover may have different absorption and/or re-emission spectra.

In the two embodiments described above, the change in the emission spectrum is achieved without changing the fabrication or processing steps used to produce the organic electronic device and without using new materials. The colored substrate and the colored device cover are commercially available.

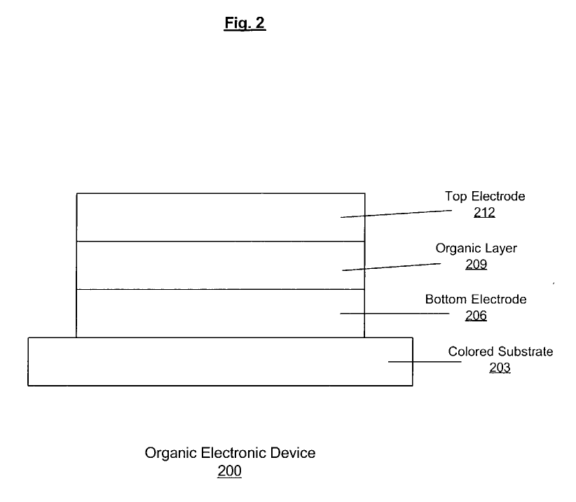

FIG. 2 shows a cross-sectional view of a first embodiment of an organic electronic device 200 according to the present invention. In this embodiment, a bottom electrode 206 is deposited on a colored substrate 203. The colored substrate 203 performs the functions of the color filter material and/or the CCM to change the emission spectrum of the light passing through the colored substrate 203. The colored substrate 203 changes the emission spectrum of light passing through it by absorbing light at certain wavelengths, or by absorbing light at certain wavelengths and reemitting a portion of the absorbed light at different wavelengths. If a portion of the absorbed light is reemitted, then the colored substrate 203 can be used as a fluorescent or phosphorescent material. The original emission spectrum can be changed so the resulting spectrum is blue-shifted or red-shifted or has a narrower spectrum (i.e., purer color). The colored substrate 203 is comprised of, for example, glass, quartz, or plastic. If comprised of glass or quartz, the colored substrate 203 may be in sheet form, but if comprised of plastic, then the colored substrate 203 may also be in continuous foil form. The materials performing the functions of the color filter and/or the CCM within the colored substrate 203 include, in general, materials that can absorb selectively over the visible spectrum, or absorb light in the visible to ultraviolet spectrum and re-emit at different wavelengths. Examples of these materials which are known in the prior art include: organic dyes or pigments, organo-metallic compounds, inorganic materials such as colored semiconductors or colored dielectric materials, and rare-earth compounds. The organic materials can be molecules, oligomers, polymers, semi-conductor nano-crystals, zinc sulfide (“ZnS”), or ZnS or doped versions thereof. For glass or quartz substrates, the color filtering/changing may be obtained via “color-centering” doping as is widely known in the prior art.

The colored substrate 203 can be fabricated by mixing the color filter material and/or the CCM with the glass, quartz, or plastic during the fabrication process or by doping the substrate with the materials after the substrate has been fabricated. The colored substrate having the characteristics described above is commercially available from, for example, Schott Corporation of Yonkers, N.Y. or Edmund Industrial Optics of Barrington, N.J.

The bottom electrode 206 can be an anode or a cathode. In this embodiment, light enters or exits the organic electronic device 200 from the bottom, therefore the bottom electrode 206 is substantially transparent. An organic layer 209 is deposited on the bottom electrode 206. If the organic electronic device 200 is an OLED, then the organic layer 209 is a light-emissive organic layer that emits light due to the recombination of holes injected from the anode and electrons from the cathode. In the OLED, the colored substrate 203 changes the emission spectrum of the light generated by the light-emissive organic layer so that a user sees a different emission spectrum than that emitted from the light-emissive organic layer. The change can be via selective absorption or absorption and reemission at different wavelengths. Use of the colored substrate 203 allows an OLED to have a wide range of emission spectrum based on a relatively small number of well-developed light-emissive organic materials.

If the organic electronic device 200 is a light detector or a solar cell, then the organic layer 209 is a light-responsive layer that generates current when it detects light. The colored substrate 203 absorbs light at certain wavelengths so that only some colors can activate the detector or the solar cell, or the colored substrate 203 absorbs light at certain wavelengths and reemits portions of the absorbed light at different wavelengths so that the emissive spectrum of the light can be changed to activate the light-responsive layer of the solar cell. For example, if the light-responsive layer is responsive only to red light and the incoming light is blue light, then the colored substrate 203 can change the blue light to red light so that the red light in effect activates the detector cell.

A top electrode 212 is deposited on the organic layer 209. The top electrode 212 can be either an anode or a cathode.

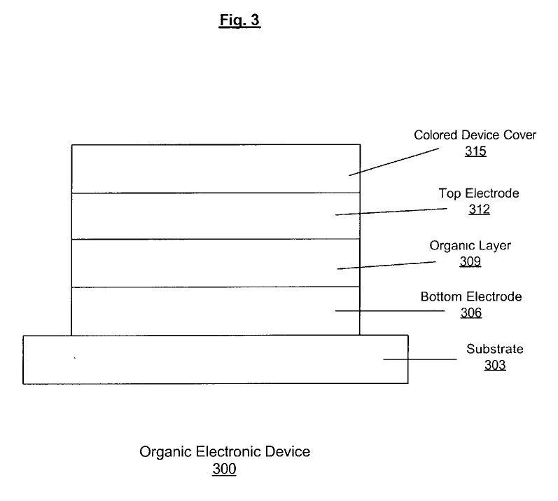

FIG. 3 shows a cross-sectional view of a second embodiment of an organic electronic device 300 according to the present invention. In this embodiment, a bottom electrode 306 is deposited on a substrate 303. The bottom electrode 306 can be an anode or a cathode. An organic layer 309 is deposited on the bottom electrode 306. If the organic electronic device 300 is an OLED, then the organic layer 309 is a light-emissive organic layer that emits light due to the recombination of holes injected from the anode and electrons from the cathode. If the organic electronic device 300 is a light detector or a solar cell, then the organic layer 309 is a light-responsive layer that generates current when it detects light.

A top electrode 312 is deposited on the organic layer 309. The top electrode 312 can be either an anode or a cathode. In this embodiment, light enters or exits the organic electronic device 300 from the top, therefore, the top electrode 312 is substantially transparent.

A colored device cover 315 is deposited on the top electrode 312. The colored device cover 315 performs the functions of the color filter material and/or the CCM to change the emission spectrum of the light passing through it. The colored device cover 315 changes the emission spectrum of light passing through it by absorbing light at certain wavelengths, or by absorbing light at certain wavelengths and reemitting a portion of the absorbed light at different wavelengths. If a portion of the absorbed light is reemitted, then the colored device cover 315 can be used as a fluorescent or phosphorescent material. The original emission spectrum can be changed so the resulting spectrum is blue-shifted or red-shifted or has a narrower spectrum (i.e., purer color). The colored device cover 315 is comprised of, for example, glass, quartz, or plastic. If comprised of glass or quartz, the colored device cover 315 may be in sheet form, but if comprised of plastic, then the colored device cover 315 may also be in continuous foil form. The materials performing the functions of the color filter and/or the CCM within the colored device cover 315 include, in general, materials that can absorb selectively over the visible spectrum, or absorb light in the visible to ultraviolet spectrum and re-emit at different wavelengths. Examples of these materials known in the prior art include: organic dyes or pigments, organo-metallic compounds, inorganic materials such as colored semiconductors or colored dielectric materials, and rare-earth compounds. The organic materials can be molecules, oligomers, polymers, semiconductor nano-crystals, zinc sulfide (“ZnS”), or ZnS or doped versions thereof. For glass or quartz covers, the color filtering/changing may be obtained via “color-centering”doping as is widely known in the prior art.

The colored device cover 315 can be fabricated by mixing the color filter material and/or the CCM with the glass, quartz, or plastic during the fabrication process or by doping the cover with the materials after the cover has been fabricated. The colored device cover having the characteristics described above is commercially available from, for example, Schott Corporation of Yonkers, N.Y. or Edmund Industrial Optics of Barrington, N.J.

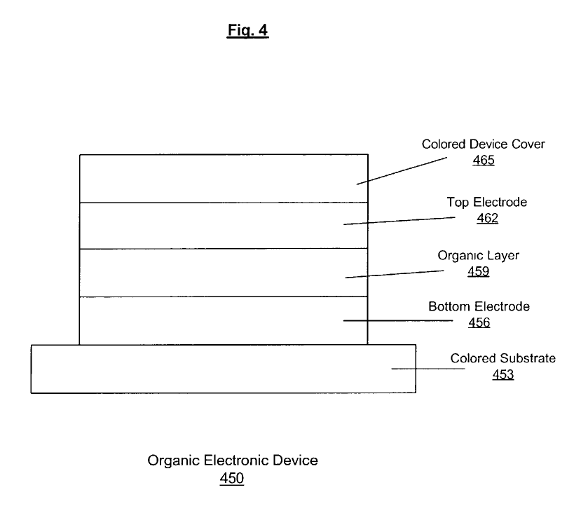

FIG. 4 shows a cross-sectional view of a third embodiment of an organic electronic device according to the present invention. In this embodiment, a bottom electrode 456 is deposited on a colored substrate 453. The colored substrate 453 changes the emission spectrum of the light passing through it and has characteristics similar to that of the colored substrate 203 described earlier. The bottom electrode 456 can be an anode or a cathode. In this embodiment, light enters or exits the organic electronic device from the top and bottom, therefore, the bottom electrode 456 and a top electrode 462 are substantially transparent. An organic layer 459 is deposited on the bottom electrode 456. If the organic electronic device 450 is an OLED, then the organic layer 459 is a light-emissive organic layer that emits light due to the recombination of holes injected from the anode and electrons from the cathode. If the organic electronic device 450 is a light detector or a solar cell, then the organic layer 459 is a light-responsive layer that generates current when it detects light. The top electrode 462 is deposited on the organic layer 459. The top electrode 462 can be either an anode or a cathode and as stated earlier, it is substantially transparent. A colored device cover 465 is deposited on the top electrode 462. The colored device cover 465 changes the emission spectrum of the light passing through it and has characteristics similar to that of the colored display cover 315 described earlier.

In this embodiment, the colored substrate 453 and the colored device cover 465 may have the same or may have different color filtering properties. For example, the colored substrate 453 and the colored device substrate 465 may have the same change of the emission spectrum by, for example, absorbing light of the same wavelengths. Where the substrate and the cover have different filtering properties, the substrate, for example, may absorb light at different wavelengths than the cover, or may absorb light at different wavelengths than the cover and reemit a portion of the absorbed light at different wavelengths than the cover.

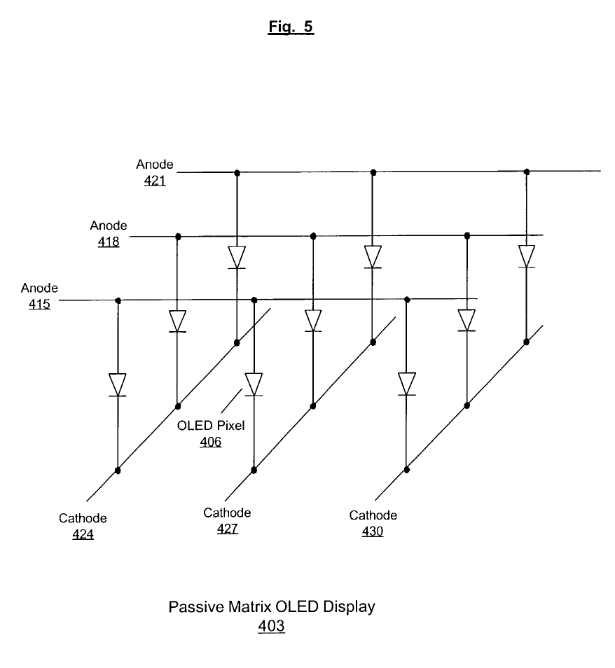

The organic electronic devices such as the OLED, solar cell, or light detector having the characteristics described earlier can be incorporated in an OLED display, a solar cell array, or a light detector array respectively. There are different types of OLED displays and they include, for example, a dot-matrix display, a segmented display, an alpha-number display, a backlight, an OLED light source, or a sign. FIG. 5 shows one type of an OLED display—a passive matrix OLED display. FIG. 5 shows an embodiment of the passive matrix OLED display 400 according to the present invention. Here, anodes of the OLED pixels are patterned parallel strips of row electrodes (e.g., an anode 415, an anode 418, and an anode 421), and cathodes of the OLED pixels are patterned parallel strips of column electrodes (e.g., a cathode 424, a cathode 427, and a cathode 430). Between the anodes and cathodes are multiple OLED pixels including an OLED pixel 406 that uses the colored substrate 203 or the colored device cover 315 to change the emission spectrum of the light produced by the emissive layer of that pixel.

If the OLED display is an alpha-numeric OLED display or a segmented display, then one of the electrodes of each OLED pixel is a common electrode and the other electrode is patterned as parallel strips of row electrodes or column electrodes. If the OLED display is an active matrix OLED display, then each OLED pixel also includes a thin film transistor and a capacitor. For the solar cell array or the light detector array, each solar cell or light detector respectively may be coupled together, for example, in series. Alternatively, the OLEDs can be used in OLED backlights or illumination elements.

The OLED displays are used in, for example, mobile communication devices (e.g., cell phones and personal digital assistants) and information displays within cars or household appliances. The OLEDs can also be used to create thin illuminating/lighting areas. Light detectors and solar cells are used to detect light and/or convert light into electricity.

As any person of ordinary skill in the art of organic electronic device fabrication will recognize from the description, figures, and examples that modifications and changes can be made to the preferred embodiments of the invention without departing from the scope of the invention defined by the following claims.

What is claimed:

1. An organic electronic device, comprising:
a colored substrate;
a bottom electrode on said colored substrate; and
an organic layer on said bottom electrode,
wherein said bottom electrode is substantially transparent and said colored substrate changes an emission spectrum of light passing through said colored substrate.

2. The organic electronic device of claim 1 wherein said colored substrate is comprised of glass, quartz, or plastic.

3. The organic electronic device of claim 2 wherein said glass and said quartz are in a sheet form and said plastic is in a sheet or a continuous foil form.

4. The organic electronic device of claim 1 wherein said organic layer is an organic light-emissive layer that emits said light at a plurality of wavelengths and said change in emission spectrum occurs by said colored substrate absorbing light at a portion of said plurality of wavelengths.

5. The organic electronic device of claim 1 wherein said organic layer is an organic light-emissive layer that emits said light at a plurality of wavelengths and said change in emission spectrum occurs by said colored substrate absorbing light at a first portion of said plurality of wavelengths and re-emitting a second portion of said absorbed light at a different wavelength.

6. The organic electronic device of claim 1 wherein said device is an organic light emitting device (“OLED”), a light detector, or a solar cell.

7. The organic electronic device of claim 6 wherein said OLED is incorporated in an OLED display, said light detector is incorporated in a light detector array, and said solar cell is incorporated in a solar cell array.

8. The organic electronic device of claim 7 wherein said OLED display is a dot-matrix display, a segmented display, or an alpha-numeric display.

9. The organic electronic device of claim 1 further comprising
a top electrode on said organic layer; and
a colored device cover on said top electrode,
wherein said top electrode is substantially transparent and said colored device cover changes an emission spectrum of light passing through said colored device cover.

10. The organic electronic device of claim 9 wherein said change in emission spectrum produced by said colored substrate is different than said change in emission spectrum produced by said colored device cover.

11. An organic electronic device, comprising:
a substrate;
a bottom electrode on said substrate;
an organic layer on said bottom electrode;
a top electrode on said organic layer; and
a colored device cover on said top electrode,
wherein said top electrode is substantially transparent and said colored device cover changes an emission spectrum of light passing through said colored device cover.

12. The organic electronic device of claim 11 wherein said colored device cover is comprised of glass, quartz, or plastic.

13. The organic electronic device of claim 12 wherein said glass and said quartz are in a sheet form and said plastic is in a sheet or a continuous foil form.

14. The organic electronic device of claim 11 wherein said organic layer is an organic light-emissive layer that emits light at a plurality of wavelengths and said change in emission spectrum occurs by said colored device cover absorbing light at a portion of said plurality of wavelengths.

15. The organic electronic device of claim 11 wherein said organic layer is an organic light-emissive layer that emits light at a plurality of wavelengths and said change in emission spectrum occurs by said colored device cover absorbing light at a first portion of said plurality of wavelengths and re-emitting a second portion of said absorbed light at a different wavelength.

16. The organic electronic device of claim 11 wherein said device is an organic light emitting device (“OLED”), a light detector, or a solar cell.

17. The organic electronic device of claim 6 wherein said OLED is incorporated in an OLED display, said light detector is incorporated in a light detector array, and said solar cell is incorporated in a solar cell array.

18. A method to fabricate an organic electronic device, comprising:
depositing a colored substrate;
depositing a bottom electrode on said colored substrate; and
depositing an organic layer on said bottom electrode,
wherein said bottom electrode is substantially transparent and said colored substrate changes an emission spectrum of light passing through said colored substrate.

19. The method of claim 18 wherein said colored substrate is comprised of glass, quartz, or plastic.

20. A method to fabricate an organic electronic device, comprising:
depositing a substrate;
depositing a bottom electrode on said substrate;
depositing an organic layer on said bottom electrode;
depositing a top electrode on said organic layer; and
depositing a colored device cover on said top electrode,
wherein said top electrode is substantially transparent and said colored device cover changes an emission spectrum of light passing through said colored device cover.

21. The method of claim 20 wherein said colored device cover is comprised of glass, quartz, or plastic.
